(19) United States
(12) Patent Application Publication
(10) Pub. No.: US 2026/0190221 A1
(43) Pub. Date: Jul. 2, 2026

(54) WIRING BOARD STACKED BODY AND METHOD OF MANUFACTURING WIRING BOARD STACKED BODY

(71) Applicant: DAIWA CO., LTD., Nagano (JP)

(72) Inventor: Eiji YOSHIMURA, Nagano (JP)

(21) Appl. No.: 18/860,690

(22) PCT Filed: May 30, 2023
(86) PCT No.: PCT/JP2023/020180

§ 371 Date: Oct. 28, 2024

(51) Int. Cl. H05K 1/03; H05K 3/00; H05K 3/18

(52) U.S. Cl. CPC H05K 1/0306; H05K 1/0353; H05K 3/0055; H05K 3/18; H05K 2203/025; H05K 2203/0703

(57) ABSTRACT

A wiring board stacked body includes: a wiring board WB having an opening; an embedded member embedded in an inside of the opening formed in the wiring board WB; a hardened material containing a thermosetting resin, disposed between the embedded member and an inner peripheral surface of the opening, and adhered to the wiring board WB; and a wiring layer formed on surfaces of the wiring board WB, the embedded member and the hardened material. The embedded member includes a ceramic body, and metal films each formed on both surfaces of the ceramic body.

### RELATED APPLICATIONS

The present application is a National Phase of International Application No. PCT/JP2023/020180 filed May 30, 2023.

### TECHNICAL FIELD

The present invention relates to a wiring board stacked body and a method of manufacturing the wiring board stacked body.

### BACKGROUND ART

To suitably cool heat generating parts such as electronic equipment including LEDs and a quad for non-lead package (QFN) that are mounted on a wiring board, there has been known a wiring board stacked body that dissipates heat from a back surface of the wiring board.

Recently, as a wiring board, there has been known a ceramic circuit board that uses ceramic having high heat conductivity such as aluminum nitride (AlN) as a board material (see patent literature 1, for example). With the use of ceramic having high heat conductivity as a board material, the wiring board can realize high heat dissipation property and heat resistance property.

### CITATION LIST

### Patent Literature

(Patent Literature 1): Japanese Patent 3690944

### SUMMARY OF INVENTION

### Technical Problem

However, in the ceramic circuit board (wiring board stacked body) described in patent literature 1, the entirety of the board is formed of ceramic and hence, there exists a drawback that it is difficult to stack the board. Further, ceramic that is relatively expensive is used for forming the entirety of the board and hence, there exists a drawback that the board becomes expensive.

The present invention has been made to overcome such problems, and it is an object of the present invention to provide a wiring board stacked body that enables easy stacking of the board and can prevent the board from becoming expensive. It is another object of the present invention to provide a method of manufacturing a wiring board stacked body that can manufacture such a wiring board stacked body.

### Solutions to Problem

[1]

A wiring board stacked body according to the present invention includes: a wiring board having an opening; an embedded member embedded in an inside of the opening formed in the wiring board; a hardened material containing a thermosetting resin, disposed between the embedded member and an inner peripheral surface of the opening, and adhered to the wiring board; and a wiring layer formed on surfaces of the wiring board, the embedded member and the thermosetting resin, wherein the embedded member includes a ceramic body, and metal films each formed on both surfaces of the ceramic body.

According to the wiring board stacked body of the present invention, the wiring board stacked body includes: the wiring board that has the opening; and the embedded member that is embedded in the opening formed in the wiring board, and the embedded member has the ceramic body. Accordingly, the wiring board stacked body can realize high heat dissipation property and high heat resistant property by using ceramic having high thermal conductivity as a board material. Further, with the use of the wiring board, stacking of the wiring board stacked body can be performed in the region of the wiring board while realizing high heat dissipation property and high heat resistant property by using ceramic as the board material. Still further, a cost of manufacturing the wiring board stacked body can be suppressed compared to a ceramic circuit board where the entirety of the board is formed using ceramic.

Further, according to the wiring board stacked body of the present embodiment, the wiring board stacked body includes: the wiring board that has the opening; and the embedded member that is embedded in the opening formed in the wiring board, and the embedded member has the ceramic body. Accordingly, the individualized ceramic bodies are used instead of one sheet of the ceramic board, and other regions are formed as wiring boards and hence, possibility of occurrence of a crack can be reduced compared to the case where only one sheet of ceramic board is used.

[2]

In the wiring board stacked body according to the present invention, it is preferable that a metal film non-formed region where the metal film is not formed be disposed on at least one surface of an outer edge portion of the embedded member, and the hardened material be disposed also between the ceramic body and the wiring layer in the metal film non-formed region.

According to the wiring board stacked body of the present invention, on at least one surface of the outer edge portion of the embedded member, the metal film non-formed region where the metal film is not formed is disposed, and the hardened material is disposed also between the ceramic body and the wiring layer in the metal film non-formed region and hence, it is possible to increase the adhesiveness between ceramic that has relatively poor adhesiveness and the wiring layer made of metal.

In a case where the metal film non-formed region is not formed, and the metal film is formed so as to cover the entirety of the ceramic body, due to a difference in thermal expansion coefficient between the metal film and the ceramic body, there is a possibility that a crack occurs in a corner portion of the ceramic body. However, according to the wiring board stacked body of the present invention, on the outer edge portion of the embedded member, the metal film non-formed region where the metal film is not formed is disposed, and the hardened material is disposed also between the ceramic body and the wiring layer in the metal film non-formed region. Accordingly, no metal film exists on the outer edge portion of the embedded member and hence, it is possible to prevent the occurrence of a crack in the corner portion of the ceramic body due to a difference in thermal expansion coefficient between the metal film and the ceramic body.

[3]

In the wiring board stacked body according to the present invention, it is preferable that the metal film non-formed region be formed on both surfaces of an outer edge portion of the embedded member, and the hardened material be also disposed between the ceramic body and the wiring layer in the both metal film non-formed regions of the ceramic body.

According to the wiring board stacked body of the present invention, on both surfaces of the ceramic body, the metal film non-formed region is disposed, and the hardened material is disposed also between the ceramic body and the wiring layer in the metal film non-formed region and hence, it is possible to increase the adhesiveness between ceramic that has relatively poor adhesiveness and the wiring layer made of metal on both surfaces of the ceramic body and, at the same time, it is possible to prevent, with certainty, the occurrence of a crack in the corner portion of the ceramic body.

[4]

In the wiring board stacked body according to the present invention, it is preferable that, as viewed in a plan view, the metal film non-formed region be formed on the entirety of the outer edge portion so as to surround the metal film.

According to the wiring board stacked body of the present invention, the metal film non-formed region is formed on the entirety of the outer edge portion so as to surround the metal film. Accordingly, cracks minimally locally occur in a portion of the outer edge portion of the ceramic body and hence, cracks further minimally occur in the ceramic body.

[5]

In the wiring board stacked body according to the present invention, it is preferable that the metal film be formed on a surface of the ceramic body by plating using direct plating.

According to the wiring board stacked body of the present invention, the metal film is a metal film formed on the surface of the ceramic body by plating using a direct plating method and hence, the ceramic body and the metal film can be bonded to each other with high adhesiveness. Further, it is unnecessary to dispose a bonding material for increasing adhesiveness between the ceramic body and the metal film and hence, it is possible to prevent lowering of heat dissipation caused by such a bonding material.

[6]

In the wiring board stacked body according to the present invention, it is preferable that a metal layer be disposed on a surface of the wiring board, and a circuit wiring be constituted of the wiring layer, the metal layer and the metal film.

According to the wiring board stacked body of the present invention, the metal layer is disposed on a surface of the wiring board, and the circuit wiring is constituted of the wiring layer, the metal layer and the metal film. Accordingly, versatile wiring structures can be constituted also in the vertical direction.

[7]

In the wiring board stacked body according to the present invention, it is preferable that the metal layer be a metal plated film that is formed on a surface of the wiring board by plating.

According to the wiring board stacked body of the present invention, the wiring layer is a metal plated film formed on the surface of the wiring board by plating. Accordingly, adhesiveness between the wiring board stacked body and the metal layer is high and hence, the stacked board having a complicated structure can be constituted easily.

[8]

In the wiring board stacked body according to the present invention, it is preferable that the opening has a rectangular shape, and the embedded member have a rectangular shape as viewed in a plan view.

According to the wiring board stacked body of the present invention, the embedded member has a rectangular shape as viewed in a plan view and hence, working can be easily applied to the embedded member and, at the same time, the alignment between the embedded member and the opening can be performed easily. Further, in a case where an electronic element is disposed on the embedded member via the wiring layer, heat can be uniformly dissipated from the electronic element that often has a rectangular shape and hence, it is possible to prevent a thermal stress from being increased locally and hence, the occurrence of crack can be further minimized.

[9]

A method of manufacturing a wiring board stacked body according to the present invention is a method of manufacturing a wiring board stacked body for manufacturing the wiring board stacked body described in any one of the above-mentioned in [1] to [3]. The method includes the steps of: obtaining a stacked body that includes: a wiring board or a wiring board material having an opening; an embedded member positioned in the opening; and a filling-use sheet or a hardened material of a coating layer containing a thermosetting resin that is integrated with the wiring board or the wiring board material, the thermosetting resin being filled between an inner surface of the opening formed in the wiring board or the wiring board material and the embedded member; and removing the hardened material by grinding the filing-use sheet or the cure material of the coating layer such that a thickness of the stacked body after grinding becomes a fixed value.

According to the method of manufacturing a wiring board stacked body of the present invention, the stacked body having the structure where the embedded member is disposed in the opening formed in the wiring board or the wiring board material, and a thermosetting resin is filled in the inside of the opening by heating and pressing is used. Accordingly, cumbersome steps are not necessary at the time of arranging the embedded member, and the method is also compatible with the embedded members having various shapes. Further, the hardened material is removed by grinding the hardened material such as the filling-use sheet or the like such that a thickness of the stacked body after grinding becomes a fixed value. Accordingly, it is possible to avoid the structure where the thermoplastic resin filled in the inside of the opening is integrally formed with the hardened material such as filling-use sheet or the like and hence, at the time ; peeling off the hardened material or the like, it is possible to minimize the occurrence of breaking, chipping or the like of the filled thermoplastic resin. Accordingly, the reliability of the structure in which the embedded member is filled and the smoothness of the surface can be increased.

[10]

It is preferable that, the method of manufacturing a wiring board stacked body according to the present invention further includes the steps of: preparing a stacked material that includes the wiring board or the wiring board material, the embedded member, and the filling-use sheet; obtaining the stacked body by integrating the stacked material by heating and pressing, and removing a hardened material of the filling-use sheet by grinding the hardened material of the filling-use sheet such that a thickness of the stacked body after grinding becomes a fixed value.

According to the method of manufacturing a wiring board stacked body according to the present invention, the embedded member is disposed in the opening formed in the wiring board or the wiring board material, and a thermosetting resin contained in the filling-use sheet can be filled in the inside of the opening and hence, the stacked body can be obtained by a dry process. In this case, at the time of arranging the embedded member, cumbersome steps are unnecessary, and the method is also compatible with embedded members having various shapes. Further, the hardened material of the filling-use sheet is removed by grinding the hardened material of the filling-use sheet such that the thickness of the stacked body after grinding becomes a fixed value. Accordingly, it is possible to avoid the structure where the thermoplastic resin filled in the inside of the opening is integrally formed with the hardened material of filling-use sheet and hence, it is possible to minimize the occurrence of breaking, chipping or the like of the filled thermoplastic resin. Accordingly, the reliability of the structure in which the embedded member is filled and the smoothness of the surface can be increased.

[11]

In the method of manufacturing a wiring board stacked body according to the present invention, it is preferable that the stacked body be a stacked body where a resin film having an opening at a position that corresponds to the opening formed in the wiring board or the wiring board material is adhered to the wiring board or the wiring board material, and the method further include a step of setting a thickness of the stacked body after grinding to the thickness of the stacked body obtained by removing a portion of the resin film at the time of removing the hardened material of the filling-use sheet or the coating layer and, further, removing a remaining portion of the resin film from the stacked body; and a step of removing the hardened material of a thermosetting resin that covers the embedded member of the stacked body.

According to the method of manufacturing a wiring board stacked body according to the present invention, by adhering the resin film to the wiring board or the wiring board material, a thermosetting resin minimally adheres to the surface of the wiring board or the like at the time of filling. Further, the resin film is interposed between the hardened material of the filling-use sheet or the like and the wiring board or the like and, at the same time, the hardened material is ground to the thickness of the wiring board stacked body where a portion of the resin film is removed and hence, it is possible to remove the hardened material with more certainty. Further, when a remaining portion of the resin film is removed from the stacked body, a height of the thermosetting resin positioned at the opening of the resin film becomes low and hence, the thermosetting resin having a protruding shape can be removed more easily.

### BRIEF DESCRIPTION OF DRAWINGS

FIG. 1 is a cross-sectional view illustrating a wiring board stacked body 10 according to an embodiment 1.

FIG. 2A to FIG. 2C are sets of views illustrating an embedded member 14 in the embodiment 1.

FIG. 3A to FIG. 3E are cross-sectional views illustrating a method of manufacturing a wiring board stacked body according to the embodiment 1.

FIG. 4A to FIG. 4D are cross-sectional views illustrating the method of manufacturing a wiring board stacked body according to the embodiment 1.

FIG. 5A to FIG. 5E are cross-sectional views illustrating the method of manufacturing a wiring board stacked body according to the embodiment 1.

FIG. 6A to FIG. 6C are cross-sectional views illustrating a method of manufacturing a wiring board stacked body according to an embodiment 2.

FIG. 7A to FIG. 7E are cross-sectional views illustrating a method of manufacturing a wiring board stacked body according to an embodiment 3.

FIG. 8A and FIG. 8B are cross-sectional views illustrating the method of manufacturing a wiring board stacked body according to the embodiment 3.

FIG. 9A to FIG. 9E are cross-sectional views illustrating the method of manufacturing a wiring board stacked body according to the embodiment 3.

FIG. 10A to FIG. 10C are cross-sectional views illustrating a method of manufacturing a wiring board stacked body according to a modification 1.

FIG. 11A to FIG. 11D are cross-sectional views illustrating a method of manufacturing a wiring board stacked body according to a modification 2.

### DESCRIPTION OF EMBODIMENTS

Hereinafter, a wiring board stacked body and a method of manufacturing a wiring board stacked body according to the embodiment of the present invention are described with reference to drawings. It must be noted that the drawings that are used for the description made hereinafter are schematic drawings that do not strictly reflect actual structures, sizes, lateral and longitudinal magnifications and the like.

### Embodiment 1

### 1. Configuration of Wiring Board Stacked Body 10 According to Embodiment 1

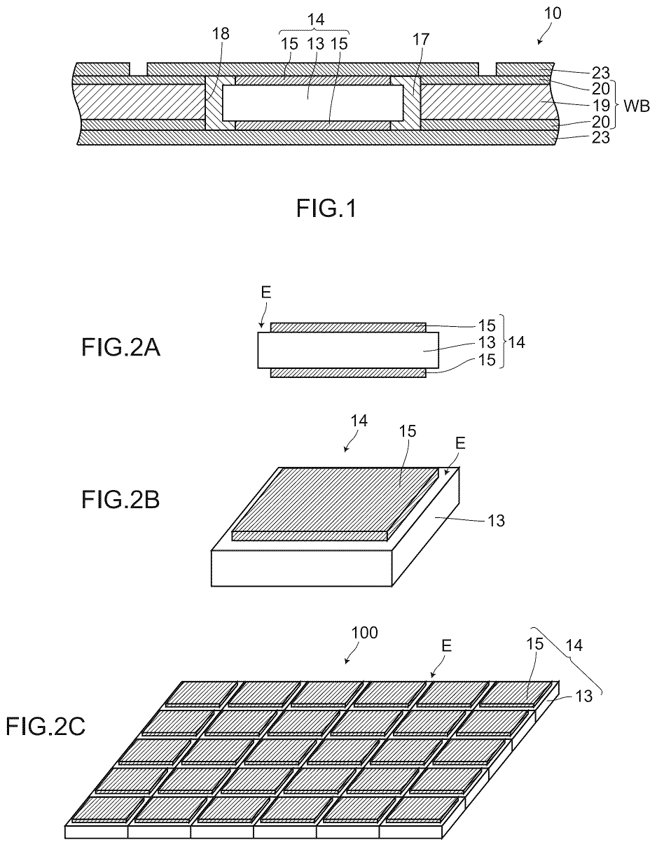

FIG. 1 is a cross-sectional view illustrating a wiring board stacked body 10 according an embodiment 1. FIG. 2A to FIG. 2C are sets of views illustrating an embedded member 14 in the embodiment 1, wherein FIG. 2A is a cross-sectional view illustrating the embedded member 14, FIG. 2B is perspective view illustrating the embedded member 14, and FIG. 2C is a view illustrating a ceramic wafer 100 that forms the embedded member 14.

The wiring board stacked body 10 according to the embodiment 1 includes, as illustrated in FIG. 1, a wiring board WB, an embedded member 14, a hardened material 17, and wiring layers 23. The wiring layers 23 are formed on both surfaces of the wiring board stacked body 10. A patten wiring is formed on the wiring layer 23 on an upper surface of the wiring board stacked body 10, and a pattern wiring is formed on an entire lower surface of the wiring board stacked body 10. The wiring layers 23 on the lower surface of the wiring board stacked body 10 can be connected to a heat sink not illustrated in the drawings.

Accordingly, in the wiring board stacked body 10, by arranging an electric element (a semiconductor chip, an LED, a reactor or the like) on the wiring layer 23 on the embedded member 14, heat generated from the electric element is transferred to the heat sink (not illustrated in the drawing) via the embedded member and the wiring layer 23 on a lower surface side, and is dissipated to the outside from the heat sink.

The wiring board WB is a both-surface cladded stacked plate where a metal layer 20 is disposed on both surfaces of an insulation layer 19. As the wiring board WB, for example, a glass epoxy board can be used. However, the wiring board WB may be a board that is formed using a suitable material described later. In the wiring board WB, the metal layer is formed on one surface (the upper surface in FIG. 1) of the insulation layer 19 by patterning. However, the metal layer may be a metal layer on which wiring is not provided. Further, in the embodiment 1, the wiring board formed of a single layer is used for facilitating the understanding of the invention in the embodiment 1, a stacked wiring board may be also used.

As a material of the insulation layer 19, a material that contains a thermosetting resin is preferable. A prepreg that contains a thermosetting resin and reinforced fibers is also preferable. As a thermosetting resin, any material can be used provided that the material is hardened by heating or the like, and has heat resistance that the wiring board is required to possess. As a thermosetting resin, specifically, various thermosetting resins such as an epoxy resin, a phenol resin and a polyimide resin can be named.

As a prepreg, it is sufficient that the prepreg contains a thermosetting resin. That is, any material can be used provided that the material is hardened by heating or the like, and has heat resistance that the wiring board is required to possess. Specifically, it is possible to name composite bodies formed of various thermosetting resin such as an epoxy resin, phenol resin, a polyimide resin or the like, and reinforcing fibers such as glass fibers, ceramic fibers, aramid fibers or paper.

Any metal may be used for forming a metal layer 20. For example, copper, a copper alloy, aluminum, stainless steel, nickel, iron, or other alloys and the like can be used. Among these materials, copper and aluminum are preferable from the viewpoint of thermal conductivity and electric conductivity.

The wiring board WB has an opening 18 at a portion thereof corresponding to the position where the embedded member 14 is disposed. The wiring board WB has, usually, a plurality of openings 18. The openings 18 can be formed by a drill, a punch, a router, or the like. It is preferable that a size of the opening 18 be slightly larger than a size of a ceramic body 13 of the embedded member 14.

Although the opening 18 has a rectangular shape as its shape, the opening 18 may adopt any shape such as a circular shape, an elliptical shape, a quadrangular shape, a shape that corresponds to an outer shape of the embedded member 14. Even in a case of a quadrangular shape or a complicated shape, it is possible to form the opening 18 having a complicated shape using a router or the like.

The embedded member 14 is embedded in the opening 18 formed in the wiring board WB. The ceramic body 13 has an approximately rectangular parallelepiped shape, and the embedded member 14 has a rectangular shape (an approximately rectangular shape) as viewed in a plan view (see FIG. 2A and FIG. 2B). However, the ceramic body 13 may have a suitable shape corresponding to the opening 18. For example, a circular shape, an elliptical shape, a quadrangular shape, and other shapes are named. With respect to a size of the embedded member 14 in a lateral direction, when the size is excessively large, the embedded member 14 is liable to fall after filling, while when the size is excessively small, the arrangement of the embedded member 14 becomes difficult. Accordingly, it is preferable that the embedded member 14 have a width of 0.1 to 20 mm at a portion of the embedded member 14 having the largest width.

The embedded member 14 includes the ceramic body 13, and the metal films 15 formed on both surfaces of the ceramic body 13 (see FIG. 2A and FIG. 2B). A thickness of the metal film 15 of the embedded member 14 and a thickness of the metal layer 20 of the wiring board WB are equal.

On both surfaces of an outer edge portion of the embedded member 14, a metal film non-formed region E where the metal film 15 is not formed is disposed. That is, on both surfaces of the embedded member 14, the ceramic body 13 is exposed over the entire circumference of an outer edge.

The embedded members 14 can be formed as individual pieces as follows. A metal film is formed on both surfaces of a ceramic board having a flat plate shape by plating using a direct plating method, the metal film is etched at a predetermined width along dicing lines for individualization, and after forming the metal film non-forming region E, the ceramic board on which the metal films are formed are cut along the dicing lines thus forming individualized embedded members 14 (see FIG. 2C with respect to the ceramic board before cutting).

As a material for forming the ceramic body 13, aluminum nitride (AlN) is used. However, alumina (Al₂O₃) or other ceramic materials can be also used.

The metal film 15 is a metal film formed on the surface of the ceramic body 13 by plating using direct plating. Any metal can be used for forming the metal film 15. For example, copper, a copper alloy, aluminum, stainless steel, nickel, iron, or other alloys and the like can be used. Among these metals, copper and aluminum are preferable from a viewpoint of thermal conductivity and electric conductivity.

The hardened material 17 contains a thermosetting resin, is disposed between the embedded member 14 and the inner peripheral surface of the opening 18 and is adhered to the wiring board WB. The hardened material 17 is also disposed between the ceramic body 13 and the wiring layer 23 in the metal film non-forming region E.

As a resin for forming the hardened material 17, it is preferable to use a resin having excellent adhesive strength with embedded member 14 and does not impair a withstand voltage characteristic and the like. Further, the resin for forming the hardened material 17 is preferably a resin that is deformed at the time of applying heating and pressure and is hardened by heating or the like, and has heat resistance property that the wiring board is required to possess. As such a resin, besides an epoxy resin, a phenol resin, and a polyimide resin, various engineering plastics can be used singly or combination of two or more. However, among such materials, an epoxy resin is preferable because of its excellent bonding force with metal. Particularly, with respect to an epoxy resin, it is more preferable to use a bisphenol A epoxy resin, a bisphenol F epoxy resin, a hydrogenated bisphenol A epoxy resin, a hydrogenated bisphenol F epoxy resin, a triblock polymer having a bisphenol A epoxy resin structure at both ends, a triblock polymer having a bisphenol F epoxy resin structure at both ends because these resins have high fluidity and excellent mixing property between metal oxide and metal nitride.

The wiring layers 23 are formed on both surfaces of the wiring board stacked body 10. That is, the wiring layers 23 are formed on surfaces of the wiring board WB, the embedded members 14 and the hardened materials 17. The wiring layers 23 are metal plated layers formed by applying metal plating to the surfaces of the wiring board WB, the embedded members 14 and the hardened materials 17. The wiring layer 23 forms a wiring pattern together with metal film 15 of the embedded members 14, and forms a wiring pattern together with the metal layer 20 of the wiring board WB.

By arranging the electronic element on the pattern wiring (particularly on the pattern wiring on the embedded member 14), heat generated from the electronic element can be dissipated to a back surface side via the wiring layer 23 on an upper surface side, the embedded member 14 and the wiring layer 23 on a lower surface side, and can be dissipated to the outside via radiation fins (not illustrated in a drawing) that are connected to a surface of the wiring layer 23 on a back surface side.

### 2. Method of Manufacturing Wiring Board Stacked Body According to Embodiment 1

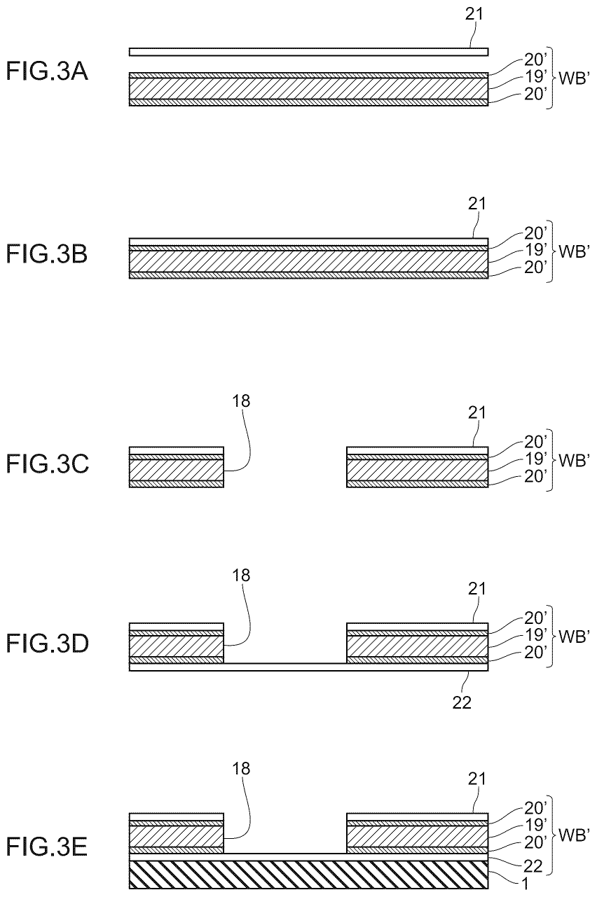

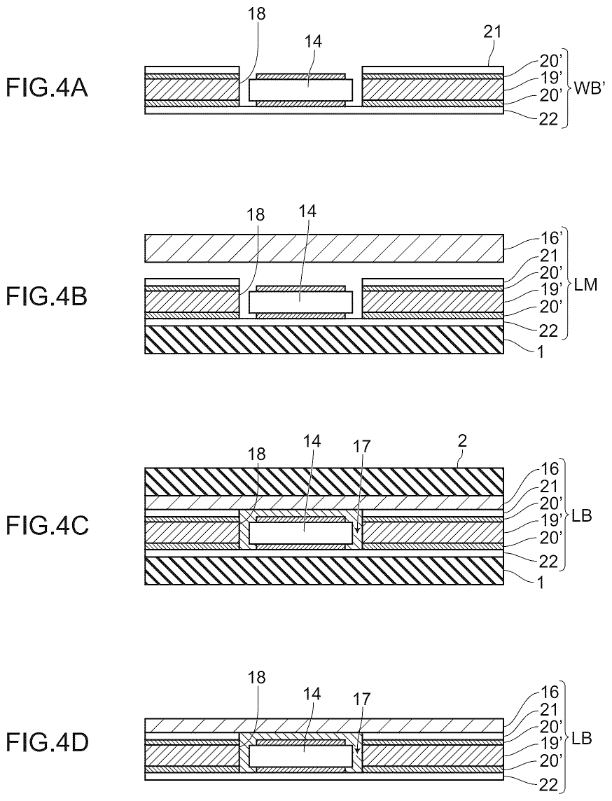

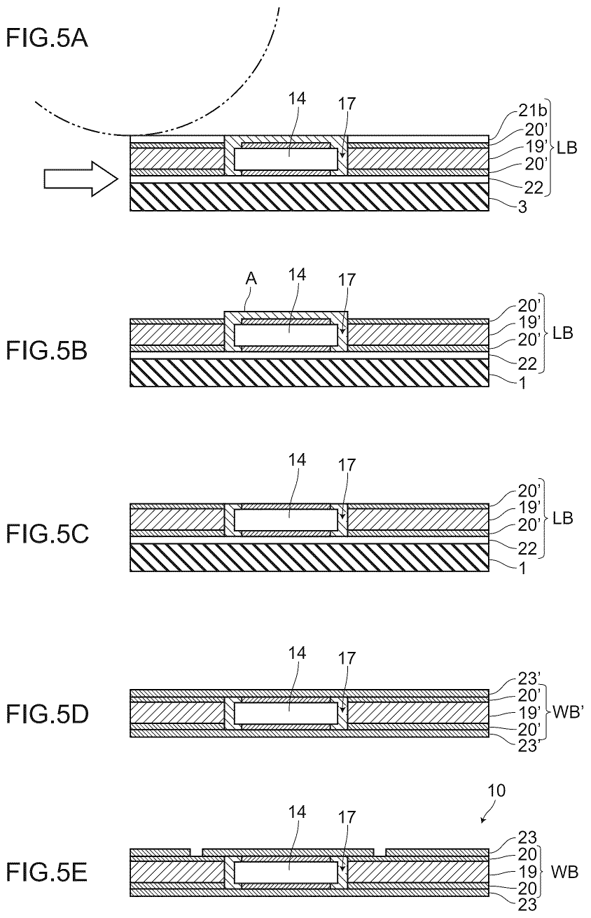

Subsequently, a method of the manufacturing a wiring board stacked body for manufacturing the wiring board stacked body 10 is described. FIG. 3A to FIG. 5E are cross-sectional views illustrating the method of manufacturing a wiring board stacked body according to the embodiment 1. FIG. 3A to FIG. 3E, FIG. 4A to FIG. 4D and FIG. 5A to FIG. 5E are respective step views.

In this embodiment, first, as illustrated in FIG. 3A and FIG. 3B, a both-surface metal cladded stacked plate is used as a wiring board material WB', and a resin film 21 (a filling sheet) is stacked on the wiring board material WB′.

The both-surface metal cladded stacked plate that is the wiring board material WB′ is formed by adhering an insulation layer 19′ in a hardened state to metal layers 20′ on both surfaces. On the other hand, the insulation layer 19′ in a half-hardened state may be used, and the insulation layer 19′ may be hardened in any desired stage. Further, it is also possible to use a both-surface metal cladded stacked plate that is formed such that two sheets of single-surface metal cladded stacked plates to each of which the insulation layer 19′ is adhered in a half-hardened state are prepared, and these single-surface metal cladded stacked plates are stacked in a state where the insulation layers 19′ face each other. Further, it is also possible to use a both-surface metal cladded stacked plate that is formed such that two sheets metal plates (metal layers 20′) are disposed in a stacked state on both sides of the insulation layer 19′ in a half-hardened state. Further, the wiring board WB may be a wiring board where the metal layer 20 on which a pattern is formed in advance is disposed on surfaces of the insulation layer 19. As a material of the insulation layer 19′ in a half-hardened state, it is preferable to use a material that contains a thermosetting resin. It is preferable that the material of the insulation layer 19′ in a half-hardened state be a prepreg that contains a thermosetting resin and reinforced fibers.

As illustrated in FIG. 3B, the resin film 21 is disposed on the wiring board material WB′. However, it is preferable to laminate resin film 21 onto the wiring board WB or the wiring board material WB′ from a viewpoint of preventing the positional displacement or from a viewpoint of preventing adhering of the hardened material 17 on a surface of the wiring board WB or the wiring board material WB′.

As the resin film 21, a film made of a resin is preferable. Any one of polyester such as polyethylene terephthalate, polyolefin such as polyethylene or polypropylene, polyamide and the like can be used. However, from a viewpoint of heat resistance, polyester such as polyethylene terephthalate is preferable. Further, in laminating the resin film 21, it is preferable to form an adhesive layer to the resin film 21. Other adhesives, a rubber-based adhesive, an acrylic adhesive, a silicone-based adhesive and the like can be used. In place of forming an adhesive layer to the resin film 21, it is possible to form the resin film 21 by applying an adhesive layer to the wiring board WB or the wiring board material WB′ additionally.

Next, as illustrated in FIG. 3C, the openings 18 are formed at portions of the wiring board material WB′ corresponding to the embedded members 14. The wiring board material WB′ usually has a plurality of openings 18. The opening 18 can be formed by drill, a punch, a router or the like. It is preferable that the size of the opening 18 be slightly larger than an upper surface of the embedded member 14.

Next, as illustrated in FIG. 3D, a support film 22 is adhered to a lower surface of the wiring board material WB′. As a support film 22, a film substantially equal to the above-mentioned resin film 21 can be used. It is preferable that the support film 22 have a substantially same adhesive layer.

Next, as illustrated in FIG. 3E, the wiring board material WB′ is placed on a support base 1.

Next, as illustrated in FIG. 4A, the embedded member 14 is disposed in the inside of the opening 18 formed in the wiring board material WB′. In this embodiment, the embedded member 14 having a thickness equal to a thickness of the wiring board material WB′ is used. It is sufficient that the embedded member 14 can be disposed in the inside of the opening 18 formed in the wiring board material WB′. In a case where the embedded member 14 has a thickness smaller than a thickness of the wiring board material WB′, when necessary, an upper surface of the embedded member 14 can be exposed by removing the hardened material 17 that covers an upper surface of the embedded member 14.

As a method of arranging the embedded members 14, the embedded members 14 may be arranged by a method that makes use of a mounting device or the like for mounting fine parts on a wiring board by surface mounting. Further, as will be described later, using embedded members 14 that are collectively formed at positions of openings formed on a support body by etching in advance, the embedded members 14 are stacked and disposed on the wiring board WB or the wiring board material WB′. However, from a viewpoint of imparting vibrations, the method where the embedded members 14 are disposed in the inside of the openings is preferable. As such a device, a commercially available feeder device that is used for arranging fine parts on the wiring board by surface mounting can be used.

As a method of imparting vibrations, in the same manner as the transfer of fine parts by a vibration feeder, a method that transfers the embedded members 14 on a surface of the wiring board material WB′ while imparting vibrations to the wiring board material WB′ and continuously arranges the embedded members 14 in the inside of openings are named. Further, a large number of embedded members 14 are supplied to the upper surface of the wiring board material WB′ in a batch method and, after vibrations are imparted to the wiring board material WB′ and/or the embedded members 14, the embedded members 14 that exist besides the openings may be removed.

A frequency and an amplitude of vibrations can be suitable set corresponding to the size or the like of the embedded members 14. For example, as the frequency, a frequency that falls within a range of from 100 to 10000 Hz is preferable. As the amplitude, an amplitude that falls within a range of from 10 μm to 1000 μm is preferable. Such a fine vibration generator can be formed of, for example, a vibrator that includes an electric magnet and an armature, a piezo transducer or an electric acoustic converter such as a ferrite vibrator.

As illustrated in FIG. 4A, from a viewpoint of arranging the embedded member 14 in the inside of the opening 18 without an offset (preferably at the center position), a method that uses a mounting device or the like is preferable. However, even in a vibration imparting method, the embedded member 14 can be disposed in the inside of the opening without an offset by arranging a jig in which an opening smaller than the opening disposed at the center position of the opening or in the vicinity of the center position of the opening is formed on an upper side of the wiring board WB or the wiring board material WB′.

Next, as illustrated in FIG. 4B, on the support base 1, a filling-use sheet 16′ that includes a hardened material 17 is stacked and disposed on the wiring board material WB′ and the embedded member 14 thus forming a stacked material LM that includes the hardened material 17 and the filling-use sheet 16′.

It is sufficient that the filling-use sheet 16′ includes the hardened material 17. Although a thermosetting-resin-made sheet may be used, it is preferable to use a prepreg that includes the hardened material 17 and reinforcing fibers. As a resin used for forming the filling-use sheet 16′, it is preferable to use a resin that exhibits excellent adhesive strength with the embedded member 14 and does not impair a withstand characteristic and the like. As such a resin, besides an epoxy resin, a phenol resin and a polyimide resin, it is possible to use various kinds of engineering plastics in a single form or in combination using two or more kinds of engineering plastics. Among these materials, an epoxy resin is preferable because the epoxy resin exhibits an excellent bonding strength between metals. Further, it is preferable that the filling-use sheet 16′ is formed of a material having high thermal conductivity. For example, a resin that contains a thermal conductive filler and the like can be named.

As a hardened material 17, any material may be used provided that the hardened material 17 is deformed at the time of applying heating and pressure and is hardened by heating or the like and, at the same time, has heat resistance that the wiring board is required to possess. As the hardened material 17, specifically, various thermosetting resins such as an epoxy resin, a phenol resin, a polyimide resin and the like can be named.

As the prepreg, any material may be used for forming the prepreg provided that the material is deformed by applying heating and pressure, hardened by heating or the like and, at the same time, has heat resistance that the wiring board is required to possess. Specifically, as the material for forming the prepreg, composite materials formed of: various thermosetting resins such as an epoxy resin, a phenol resin, a polyimide resin and the like; and reinforcing fibers such as glass fibers, ceramic fibers, aramid fibers, a paper and the like can be named.

Next, FIG. 4C illustrates an example including a step where the stacked material LM is integrated by applying heat and pressure thus obtaining a stacked body LB where the hardened material 17 is filled between the inner surface of the opening formed in the wiring board material WB′ and the embedded member 14. In the illustrated example, with such a configuration, it is possible to form the stacked body LB where the height of the embedded member 14 is equal to the height of the surface of the wiring board WB or the wiring board material WB′.

Further, as illustrated in FIG. 4C and FIG. 4D, the filling-use sheet 16′ becomes a hardened material 16 having a thinner thickness by heating and pressing and hence, a state is brought about where the hardened material 17 is filled between the opening portion 18 formed in the wiring board WB or the wiring board material WB′, and an upper surface of the embedded member 14 is covered by the hardened material 17 of the filling-use sheet 16′. Further, in a metal film non-formed region E where a metal film is not formed, the hardened material 17 is disposed also between the ceramic body 13 and the wiring layer 23.

In applying heat and pressure, a method can be adopted where the stacked material LM is disposed on the support base 1, and heating and pressing are performed by a press plate or the like. As a method of performing heating and pressing, heating and pressing may be performed using a heating and pressing device (a thermal laminator, a heating press). In this case, to avoid the inclusion of air, vacuum (a vacuum laminator) may be used as an atmosphere. Particularly, in a case where the support film 22 is laminated to a lower surface of the metal layer 20, there is no place for air in the opening to escape and hence, it is preferable to perform heating and pressing under a reduced pressure atmosphere. Conditions such as a heating temperature and a pressure may be suitably set corresponding to a material and a thickness of the filling sheet 16′. It is preferable that the pressure is set to a value that falls within a range of 0.5 to 30 MPa.

Next, as illustrated in FIG. 5A, the hardened material 16 of the coating layer is ground such that the thickness of stacked body LB after grinding becomes a fixed value, and the hardened material 16 is removed. In this embodiment, an example is described where, at the time of removing the hardened material 16, the thickness of the stacked body LB after grinding is set to the thickness at which a portion of the resin film 21 is removed. Accordingly, the entity of the hardened material 16 is removed and, at the same time, the portion of the resin film 21 is removed. It is needless to say that only the entirety of the hardened material 16 may be removed, or the entirety of the hardened material 16 and the resin film 21 may be removed.

As a device that can grind the hardened material 16 of the coating layer such that the thickness of the stacked body LB becomes a fixed value, a commercially available table-movable belt sander in a market can be used. In FIG. 5A, a grinding belt that is supported on a surface of a rotatable roll is indicated by an imaginary line. In the actual device, the grinding belt has a larger radius of curvature with respect to a grinding object, and a fixed distance is provided between the grinding belt that moves together with the roll and the moving a table 3. By making the stacked body LB pass through the distance, grinding can be performed such that the thickness of the stacked body LB becomes a fixed value.

Next, as illustrated in FIG. 5B, the method includes a step of peeling off a remaining portion 21b of the resin film 21 from the stacked body LB. By performing such a step, the hardened material 17 that covers the embedded member 14 remains and hence, a protruding portion A formed of the hardened material 17 is formed.

Next, as illustrated in FIG. 5C, the method includes a step of removing the protruding portion A of the hardened material 17 that covers the embedded member 14 of the stacked body LB. By performing such a step, an upper surface of the stacked body LB can be flattened. In the embodiment 1, prior to the removal of the protruding portion A, the resin film 21 is removed. However, the resin film 21 can be removed simultaneously with the removal of the protruding portion A.

As a method of removing the protruding portion A, it is preferable to use method that removes the protruding portion by grinding or polishing. As such a method, a method that uses a grinding device having a hard rotary blade that is formed by arranging a plurality of hard blades made of diamond or the like on a rotary plate in a radial direction is used, a method that uses a sander, a belt sander, a grinder, a surface grinding machine, a hard abrasive molded product and the like are named.

Next, a step of peeling off at least the support film 22 (a lower surface side) from the stacked body LB is performed. It is preferable that an adhesive strength between the embedded member 14 and the support film 22 be set smaller than an adhesive strength between the embedded member 14 and the hardened material 17 at the time of peeling off the support film 22. By setting adhesive strengths as described above, the support film 22 can be easily peeled off.

Next. as illustrated in FIG. 5D, metal plating is applied to the exposed embedded member 14 and the metal layer 20′ thus forming a metal plated layer 23′ (both surfaces). As a kind of metal of metal plating, for example, copper, silver, Ni or the like is preferably used. As a method of forming the metal plated layer 23′, for example, the combination of electroless plating or the like and electrolytic plating can be named.

Next, as illustrated in FIG. 5E, a metal plated layer 23′ and a metal layer 20′ are formed by patterning thus forming the wiring layer 23. In pattern forming, the patterned wiring layer 23 is formed by etching the metal plated layer 23′ and the metal layer 20′ in a predetermined pattern using an etching resist, for example. The metal film 15 may be etched.

The wiring board stacked body 10 can be manufactured in accordance with the above-mentioned steps.

### 3. Advantageous Effects of the Wiring Board Stacked Body 10 and the Method of Manufacturing a Wiring Board Stacked Body According to Embodiment 1

According to the wiring board stacked body 10 of the embodiment 1, the wiring board stacked body 10 includes: the wiring board WB that has the opening 18; and the embedded member 14 that is embedded in the opening 18 formed in the wiring board WB, and the embedded member 14 has the ceramic body 13. Accordingly, the wiring board stacked body 10 can realize high heat dissipation property and high heat resistant property by using ceramic having high thermal conductivity as a board material. Further, with the use of the wiring board WB, stacking of the wiring board stacked body 10 can be performed in the region of the wiring board WB while realizing high heat dissipation property and high heat resistant property by using ceramic as the board material. Still further, a cost of manufacturing the wiring board stacked body 10 can be suppressed compared to a ceramic circuit board where the entirety of the board is formed using ceramic.

Further, according to the wiring board stacked body 10 of the embodiment 1, the wiring board stacked body 10 includes: the wiring board WB that has the opening 18; and the embedded member 14 that is embedded in the opening 18 formed in the wiring board WB, and the embedded member 14 has the ceramic body 13. Accordingly, the individualized ceramic bodies 13 are used instead of one sheet of the ceramic board, and other regions are formed as wiring boards and hence, possibility of occurrence of a crack can be reduced compared to the case where only one sheet of ceramic board is used.

According to the wiring board stacked body 10 of the embodiment 1, on the outer edge portion of the embedded member 14, the metal film non-formed region E where the metal film 15 is not formed is disposed, and the hardened material 17 is disposed also between the ceramic body 13 and the wiring layer 23 in the metal film non-formed region E and hence, it is possible to increase the adhesiveness between the ceramic body 13 made of ceramic that has relatively poor adhesiveness and the wiring layer 23 made of metal.

According to the wiring board stacked body 10 of the embodiment 1, on both surfaces of the ceramic body 13, the metal film non-formed region E is formed, and the hardened material 17 is disposed also between the ceramic body 13 and the wiring layer 23 in the metal film non-formed region E. Accordingly, it is possible to increase the adhesiveness between the ceramic body 13 that has relatively poor adhesiveness and the wiring layer 23 on both surfaces of the ceramic body 13 and, at the same time, it is possible to prevent the occurrence of a crack at a corner portion of the ceramic body 13 with more certainty.

According to the wiring board stacked body 10 of the embodiment 1, the metal film non-formed region E is formed on the entirety of the outer edge portion so as to surround the metal film 15. Accordingly, cracks minimally locally occur in a portion of the outer edge portion of the ceramic body 13 and hence, cracks further minimally occur in the ceramic body 13.

According to the wiring board stacked body 10 of the embodiment 1, the metal film 15 is a metal film formed on the surface of the ceramic body 13 by plating using a direct plating method and hence, the ceramic body 13 and the metal film 15 can be bonded to each other with high adhesiveness. Further, it is unnecessary to dispose a bonding material for increasing adhesiveness between the ceramic body 13 and the metal film 15 and hence, it is possible to prevent lowering of heat dissipation property caused by such a bonding material.

According to the wiring board stacked body 10 of the embodiment 1, the wiring layer 23 is formed on the surface of the wiring board WB, and the circuit wiring is constituted of the wiring layer 23, the metal layer 20 and the metal film 15. Accordingly, it is possible to constitute the wiring pattern having the complicated constitution.

According to the wiring board stacked body 10 of the embodiment 1, the wiring layer 23 is a metal plated film formed on the surface of the wiring board WB by plating. Accordingly, adhesiveness between the wiring board WB and the wiring layer 23 is high and hence, the stacked board having a complicated structure can be constituted easily.

According to the wiring board stacked body 10 of the embodiment 1, the embedded member 14 has a rectangular shape as viewed in a plan view and hence, working can be easily applied to the embedded member 14 and, at the same time, the alignment between the embedded member 14 and the opening can be performed easily. Further, in a case where an electronic element is disposed on the embedded member 14 via the wiring layer 23, heat can be uniformly dissipated from the electronic element that often has a rectangular shape and hence, it is possible to prevent a thermal stress from being increased locally and hence, the occurrence of crack can be further minimized.

According to the method of manufacturing a wiring board stacked body according to the embodiment 1, the stacked body having the structure where the embedded member 14 is disposed in the opening formed in the wiring board WB or the wiring board material WB′, and a thermosetting resin is filled in the inside of the opening by heating and pressing is used. Accordingly, cumbersome steps are not necessary at the time of arranging the embedded member 14, and the method is also compatible with the embedded members having various shapes. Further, the hardened material is removed by grinding the hardened material such as the filling-use sheet 16′ or the like such that a thickness of the stacked body after grinding becomes a fixed value. Accordingly, it is possible to avoid the structure where the thermoplastic resin filled in the inside of the opening 18 is integrally formed with the hardened material such as filling-use sheet or the like and hence, at the time of peeling off the hardened material or the like, it is possible to minimize the occurrence of breaking, chipping or the like of the filled thermoplastic resin. Accordingly, the reliability of the structure in which the embedded member is filled and the smoothness of the surface can be increased.

According to the method of manufacturing a wiring board stacked body according to the embodiment 1, the embedded member 14 is disposed in the opening 18 formed in the wiring board WB or the wiring board material WB′, and a thermosetting resin contained in the filling-use sheet 16′ (by heating and pressing) can be filled in the inside of the opening and hence, the stacked body can be obtained by a dry process. In this case, at the time of arranging the embedded member, cumbersome steps are unnecessary, and the method is also compatible with embedded members having various shapes. Further, the hardened material of the filling-use sheet is removed by grinding the hardened material of the filling-use sheet such that the thickness of the stacked body after grinding becomes a fixed value. Accordingly, it is possible to avoid the structure where the thermoplastic resin filled in the inside of the opening is integrally formed with the hardened material of filling-use sheet and hence, it is possible to minimize the occurrence of breaking, chipping or the like of the filled thermoplastic resin. Accordingly, the reliability of the structure in which the embedded member is filled and the smoothness of the surface can be increased.

According to the method of manufacturing a wiring board stacked body according to the embodiment 1, by adhering the resin film to the wiring board WB or the wiring board material WB′, a thermosetting resin minimally adheres to the surface of the wiring board or the like at the time of filling. Further, the resin film is interposed between the hardened material of the filling-use sheet or the like and the wiring board or the like and, at the same time, the hardened material is ground to the thickness of the wiring board stacked body where a portion of the resin film is removed and hence, it is possible to remove the hardened material with more certainty. Further, when a remaining portion of the resin film is removed from the stacked body, a height of the thermosetting resin positioned at the opening of the resin film becomes low and hence, the thermosetting resin having a protruding shape can be removed more easily.

### Embodiment 2

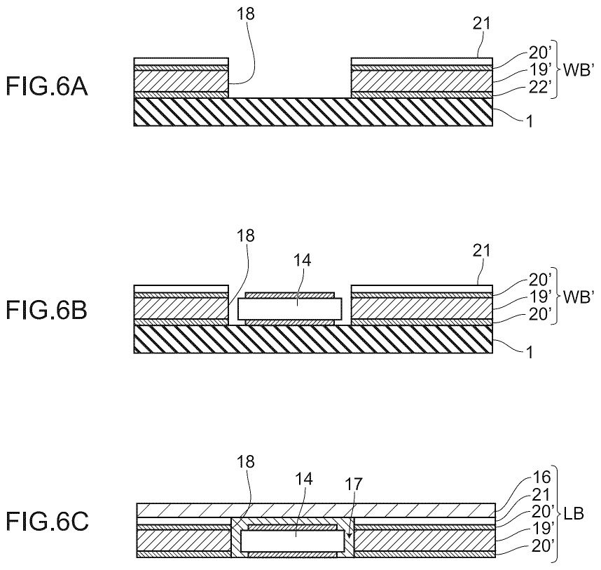

FIG. 6A to FIG. 6C are cross-sectional views illustrating a method of manufacturing a wiring board stacked body according to an embodiment 2. FIG. 6A to FIG. 6C are respective step views. The method of manufacturing a wiring board stacked body according to the embodiment 2 has substantially the same steps as the method of manufacturing a wiring board stacked body according to the embodiment 1 basically. However, the method of manufacturing a wiring board stacked body according to the embodiment 2 differs from the wiring board stacked body manufacturing methods according to the embodiment 1 with respect to a point that the method does not use the support film 22.

According to the embodiment 2, as illustrated in FIG. 6A, in a state where a wiring board material WB′ is placed on a support base 1 such as a mirror-finished plate or the like, an embedded member 14 is disposed in the inside of an opening formed in the wiring board material WB′ (see FIG. 6B).

Next, a filling-use sheet that includes a hardened material 17 is placed, and heating and pressing are applied to the filing-use sheet (see FIG. 6C). Accordingly, the wiring board material WB′ and the filling-use sheet are integrally formed and hence, a step of obtaining a stacked body LB where the hardened material 17 is filled between an inner surface of an opening 18 of the wiring board WB or the wiring board material WB′ and the embedded member 14 is performed. In performing such a step, there may be a case where the hardened material 17 adheres to a periphery of the opening on a lower surface of the wiring board WB or the wiring board material WB′. However, the adhered hardened material 17 can be removed by grinding or chemical treatment.

The succeeding steps that follow the above-mentioned step are substantially equal to the steps performed in the method of manufacturing a wiring board stacked body according to the embodiment 1 except for the step of removing the support film and hence, the description of these steps is omitted.

In this manner, the method of manufacturing a wiring board stacked body according to the embodiment 2 differs from the case of the method of manufacturing a wiring board stacked body according to the embodiment 1 with respect to the point that the support film 22 is not used. However, in the same manner as the case of the method of manufacturing a wiring board stacked body according to the embodiment 1, the method uses the stacked body having the structure where the embedded member is disposed in the opening formed in the wiring board or the wiring board material, and a thermosetting resin is filled in the inside of the opening by heating and pressing. Accordingly, at the time of arranging the embedded member, cumbersome steps are not necessary, and the method is compatible with embedded members having various shapes. Further, the hardened material such as the filling sheet is removed by grinding the hardened material such that the thickness of the stacked body after grinding becomes a fixed value. Accordingly, it is possible to prevent the wiring body stacked body from having the structure where the thermoplastic resin filled in the inside of the opening is integrally formed with the hardened material such as the filling-use sheet and hence, it is possible to minimize the occurrence of breaking, chipping or the like of the filled thermoplastic resin at the time of peeling off the hardened material. Accordingly, the reliability of the structure in which the embedded member is filled and the smoothness of the surface can be increased.

Accordingly, the method of manufacturing a wiring board stacked body according to the embodiment 2 has basically substantially the same steps as the method of manufacturing a wiring board stacked body according to the embodiment 1 with respect to the points other than the point that the method of manufacturing a wiring board stacked body according to the embodiment 2 does not use the support film 22. Accordingly, the method of manufacturing a wiring board stacked body according to the embodiment 3 acquires advantageous effects that are equal to the advantageous effects of the method of manufacturing a wiring stacked body according to the embodiment 1 amongst all advantageous effects acquired by the method of manufacturing a wiring stacked body according to the embodiment 1.

### Embodiment 3

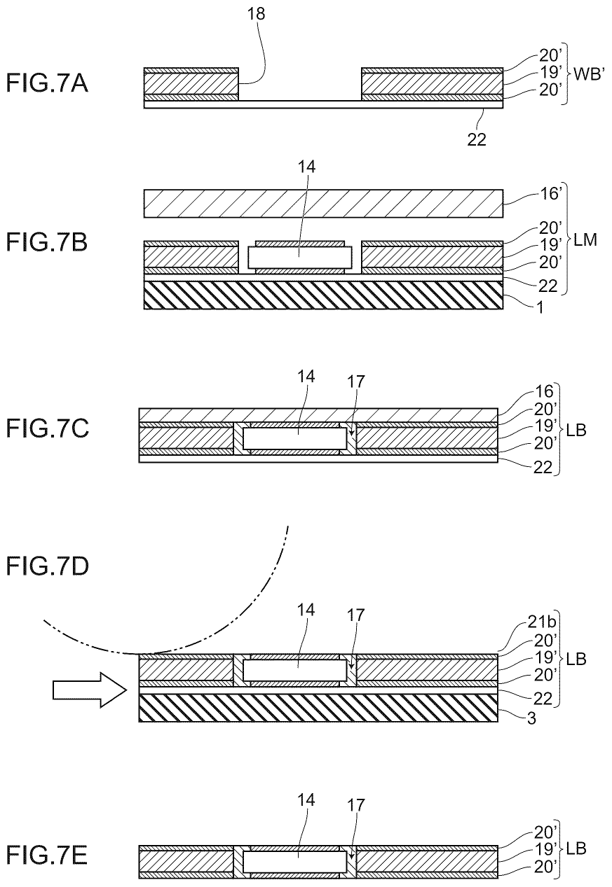

FIG. 7A to FIG. 7E are cross-sectional views illustrating a method of manufacturing a wiring board stacked body according to an embodiment 3. FIG. 7A to FIG. 7E are respective step views. The method of manufacturing a wiring board stacked body according to the embodiment 3 has substantially the same steps as the method of manufacturing a wiring board stacked body according to the embodiment 1 basically. However, the method of manufacturing a wiring board stacked body according to the embodiment 3 differs from the method of manufacturing a wiring board stacked body manufacturing methods according to the embodiment 1 with respect to a point that the method of manufacturing a wiring board stacked body according to the embodiment 3 does not use the resin film 21.

In the embodiment 3, A stacked material LM that includes: a wiring board material WB′ that includes an opening 18 and to which a resin film 21 does not adhere (see FIG. 7A); an embedded member 14 that is positioned in the inside of the opening; and a filling-use sheet 16′ that is stacked on the wiring board material WB′ and includes a hardened material 17, is prepared (see FIG. 7B). In this embodiment, a support film 22 is adhered to a lower surface of the wiring board material WB′.

Next, in the same manner as the previous embodiment, the stacked material LM is integrated by heating and pressing thus obtaining a stacked body LB where the hardened material 17 is filled between an inner surface of the opening 18 formed in the wiring board material WB′ and the embedded member 14. With such a configuration, it is possible to form the stacked body LB where a height of the embedded member 14 is equal to a height of the surface of the wiring board material WB′.

Next, as described in FIG. 7D, the hardened material 16 of the filling-use sheet 16′ is ground such that the thickness of the stacked body LB after grinding becomes a fixed value thus removing the hardened material 16 of the filling-use sheet 16′. In this embodiment, in removing the hardened material 16 of the filling-use sheet 16′, the thickness of the stacked body LB after grinding is set to a thickness that the entirety or the substantially the entirety of the hardened material 16 is completely removed. Accordingly, the entirety or the substantially the entirety of the hardened material 16 is removed.

Next, the support film 22 is removed. The succeeding steps that follow the above-mentioned step are substantially equal to the steps performed in the method of manufacturing a wiring board stacked body according to the embodiment 1 and hence, the description of these steps is omitted. The wiring board stacked body 10 according to the embodiment 3 can be manufactured in this manner (see FIG. 7E) .

In this manner, the method of manufacturing a wiring board stacked body according to the embodiment 3 differs from the case of the method of manufacturing a wiring board stacked body according to the embodiment 1 with respect to the point that the resin film 21 is not used. However, in the same manner as the case of the method of manufacturing a wiring board stacked body according to the embodiment 1, the wiring board manufacturing method according to the embodiment 3 uses the stacked body having the structure where the embedded member is disposed in the opening formed in the wiring board or the wiring board material, and a thermosetting resin is filled in the inside of the opening by heating and pressing is used. Accordingly, cumbersome steps are not necessary at the time of arranging the embedded member, and the manufacturing method is also compatible with the embedded members having various shapes. Further, the hardened material is removed by grinding the hardened material such as the filling-use sheet or the like such that a thickness of the stacked body after grinding becomes a fixed value. Accordingly, it is possible to avoid the structure where the thermoplastic resin filled in the inside of the opening is integrally formed with the hardened material such as filling-use sheet or the like and hence, at the time ; peeling off the hardened material or the like, it is possible to minimize the occurrence of breaking, chipping or the like of the filled thermoplastic resin. Accordingly, the reliability of the structure in which the embedded member is filled and the smoothness of the surface can be increased.

The method of manufacturing a wiring board stacked body according to the embodiment 3 has basically substantially the same steps as the method of manufacturing a wiring board stacked body according to the embodiment 1 with respect to the points other than the point that the resin film 21 is not used. Accordingly, the method of manufacturing a wiring board stacked body according to the embodiment 3 acquires advantageous effects that are equal to the advantageous effects of the method of manufacturing a wiring stacked body according to the embodiment 1 amongst all advantageous effects acquired by the method of manufacturing a wiring stacked body according to the embodiment 1.

### Embodiment 4

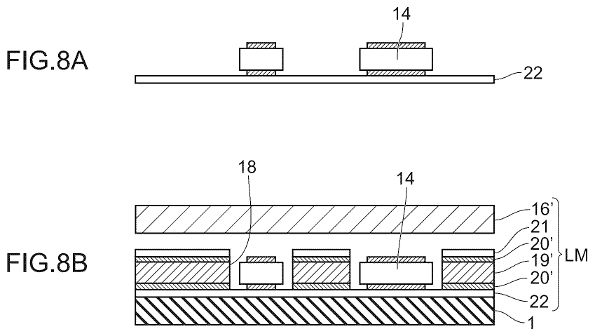

FIG. 8A and FIG. 8B are cross-sectional views illustrating a method of manufacturing a wiring board stacked body according to an embodiment 4. FIG. 8A and FIG. 8B are respective step views. The method of manufacturing a wiring board stacked body according to the embodiment 4 has substantially the same steps as the method of manufacturing a wiring board stacked body according to the embodiment 1 basically. However, the method of manufacturing a wiring board stacked body according to the embodiment 4 differs from the method of manufacturing a wiring board stacked body according to the embodiment 1 with respect to a point that an embedded member 14 is disposed on a support film 22 in a preceding stage where a wiring board material WB is arranged.

In the embodiment 4, as illustrated in FIG. 8A, the embedded member 14 is disposed on the support film 22 in the preceding stage where the wiring board material WB′ is disposed and, thereafter, the wiring board material WB is disposed on the support film 22 while making the wiring board material WB aligned with the embedded member 14, and a filling-use sheet 16′ is disposed on the wiring board material WB and the embedded member 14.

The succeeding steps that follow the above-mentioned step are substantially equal to the steps performed in the method of manufacturing a wiring board stacked body according to the embodiment 1 and hence, the description of these steps is omitted.

In this manner, the method of manufacturing a wiring board stacked body according to the embodiment 4 differs from the case of the method of manufacturing a wiring board stacked body according to the embodiment 1 with respect to the point that the embedded member 14 is disposed on the support film 22 in the preceding stage where the wiring board material WB is arranged. However, in the same manner as the case of the method of manufacturing a wiring board stacked body according to the embodiment 1, the stacked body having the structure where the embedded member is disposed in the opening formed in the wiring board or the wiring board material, and a thermosetting resin is filled in the inside of the opening by heating and pressing is used. Accordingly, cumbersome steps are not necessary at the time of arranging the embedded member, and the method is also compatible with the embedded members having various shapes. Further, the hardened material is removed by grinding the hardened material such as the filling-use sheet or the like such that a thickness of the stacked body after grinding becomes a fixed value. Accordingly, it is possible to avoid the structure where the thermoplastic resin filled in the inside of the opening is integrally formed with the hardened material such as filling-use sheet or the like and hence, at the time of peeling off the hardened material or the like, it is possible to minimize the occurrence of breaking, chipping or the like of the filled thermoplastic resin. Accordingly, the reliability of the structure in which the embedded member is filled and the smoothness of the surface can be increased.

The method of manufacturing a wiring board stacked body according to the embodiment 4 has basically substantially the same steps as the method of manufacturing a wiring board stacked body according to the embodiment 1 with respect to the points other than the point that the embedded member 14 is disposed on the support film 22 in a preceding stage where the wiring board material WB is arranged. Accordingly, the method of manufacturing a wiring board stacked body according to the embodiment 4 acquires advantageous effects that are equal to the advantageous effects of the method of manufacturing a wiring stacked body according to the embodiment 1 amongst all advantageous effects acquired by the method of manufacturing a wiring stacked body according to the embodiment 1.

### Embodiment 5

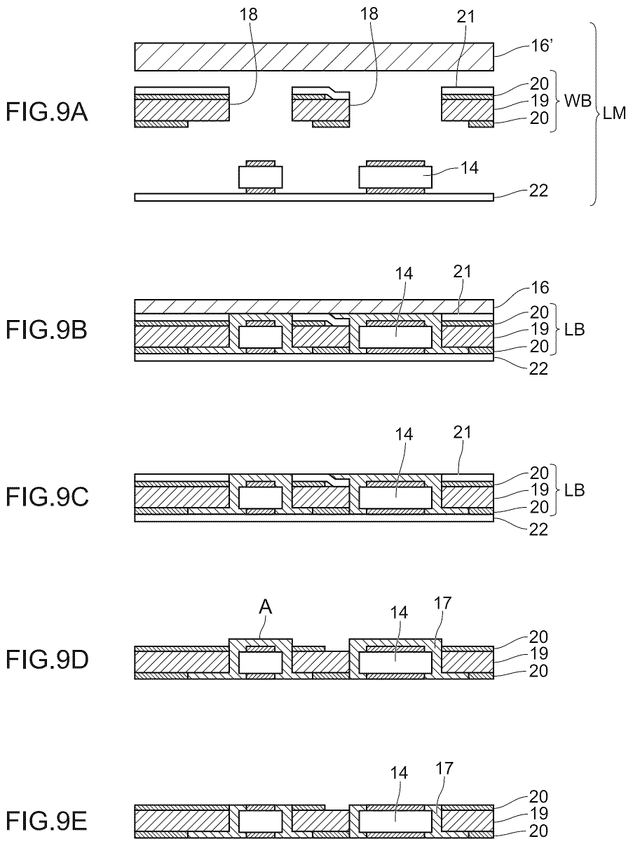

FIG. 9A to FIG. 9E are cross-sectional views illustrating a method of manufacturing a wiring board stacked body according to an embodiment 5. FIG. 9A to FIG. 9E are respective step views. The method of manufacturing a wiring board stacked body according to the embodiment 5 has substantially the same steps as the method of manufacturing a wiring board stacked body according to the embodiment 1 basically. However, the method of manufacturing a wiring board stacked body according to the embodiment 5 differs from the method of manufacturing a wiring board stacked body according to the embodiment 1 with respect to a point that a wiring board WB that includes wiring patterns 20 that form metal layers and an insulation layer 19 is used in place of the wiring board material WB.

As illustrated in FIG. 9A, a support film 22 on which embedded members 14 are formed; and a stacked material LM that has a wiring board WB having a plurality of openings 18 at portions thereof corresponding to the embedded members 14, and a filling-use sheet 16′ that contains a hardened material 17 are stacked such that the embedded members 14 are positioned in the inside of the respective openings 18. In this case, it is preferable that an upper surface of the wiring board WB be covered by a resin film 21 and the resin film 21 have a plurality of openings 21a in portions thereof that correspond to the embedded members 14.

Next, as illustrated in FIG. 9B, a step is carried out where the stacked material LM is integrated by heating and pressing thus obtaining a stacked body LB where the hardened material 17 is filled between an inner surface of the opening 18 formed in the wiring board WB and the embedded member 14. With such a configuration, it is possible to form the stacked body LB where a height of the embedded member 14 is set equal to or slightly lower than an upper surface of the wiring board WB. Such a step can be performed in the same manner as the embodiments described above.

Then, as illustrated in FIG. 9C, in the same manner as the previous embodiments, a step is performed where the hardened material 16 of the filling-use sheet 16′ is removed by grinding the hardened material 16 of the filling sheet 16′ such that a thickness of the stacked body LB after grinding becomes a fixed value. In this embodiment, an example is exemplified where, in removing the hardened material 16 of the filling-use sheet 16′, a thickness of the stacked body LB after grinding is set to a thickness at which a portion of the resin film 21 is removed. With such a step, the entirety of the hardened material 16 is removed and, at the same time, the portion of the resin film 21 is removed. It is needless to say that only the entirety of the hardened material 16 may be removed.

Next, as illustrated in FIG. 9D and FIG. 9E, a resin film 21 on an upper surface is peeled off, and a thermosetting resin (a protruding portion A) that covers an upper surface of the embedded member 14 is removed. In a case where the upper surface of the embedded member 14 is higher than an upper surface of the wiring board WB, it is also possible to remove an amount of embedded member 14 by an amount corresponding to the difference when necessary.

Accordingly, it is possible to obtain the wiring board that includes: the insulation layer 19; the embedded member 14 embedded in the insulation layer 19; and the wiring layer (the wiring pattern 20), the insulation layer 19 contains the hardened material 16 of the filling-use sheet 16′, and a periphery of the embedded member 14 is made to adhere the insulation layer 19 by a hardened material 17 that differs from a resin component of the insulation layer 19.

As illustrated in the drawings, in a case of using a both-surface wiring board, it is preferable to use an interlayer connection structure such as a plated through hole, a metal bump, a filled via, or a plated via.

In this manner, the method of manufacturing a wiring board stacked body according to the embodiment 5 differs from the case of the method of manufacturing a wiring board stacked body according to the embodiment 1 with respect to the point that the wiring board WB that includes the wiring pattern 20 and the insulation layer 19 is used in place of the wiring board material WB. However, in the same manner as the case of the method of manufacturing a wiring board stacked body according to the embodiment 1, the stacked body having the structure where the embedded member is disposed in the opening formed in the wiring board or the wiring board material, and a thermosetting resin is filled in the inside of the opening by heating and pressing is used. Accordingly, cumbersome steps are not necessary at the time of arranging the embedded member, and the method is also compatible with the embedded members having various shapes. Further, the hardened material is removed by grinding the hardened material such as the filling-use sheet or the like such that a thickness of the stacked body after grinding becomes a fixed value. Accordingly, it is possible to avoid the structure where the thermoplastic resin filled in the inside of the opening is integrally formed with the hardened material such as filling-use sheet or the like and hence, at the time 41 ; peeling off the hardened material or the like, it is possible to minimize the occurrence of breaking, chipping or the like of the filled thermoplastic resin. Accordingly, the reliability of the structure in which the embedded member is filled and the smoothness of the surface can be increased.

The method of manufacturing a wiring board stacked body according to the embodiment 5 has basically substantially the same steps as the method of manufacturing a wiring board stacked body according to the embodiment 1 with respect to the points other than the point that the wiring board WB that includes the wiring pattern 20 and the insulation layer 19 is used in place of the wiring board material WB. Accordingly, the method of manufacturing a wiring board stacked body according to the embodiment 5 acquires advantageous effects that are equal to the advantageous effects of the method of manufacturing a wiring stacked body according to the embodiment 1 amongst all advantageous effects acquired by the method of manufacturing a wiring stacked body according to the embodiment 1.

Heretofore, the present invention has been described with reference to the above-mentioned embodiments. However, the present invention is not limited to the above-mentioned embodiments, and can be carried out in various modes without departing from the gist of the present invention and, for example, the following modifications are conceivable.

(1) In the above-mentioned respective embodiments, the number, materials, shapes, positions and sizes of constitutional elements are provided for an exemplifying purpose, and can be changed within a scope that advantageous effects of the present invention are not impaired.

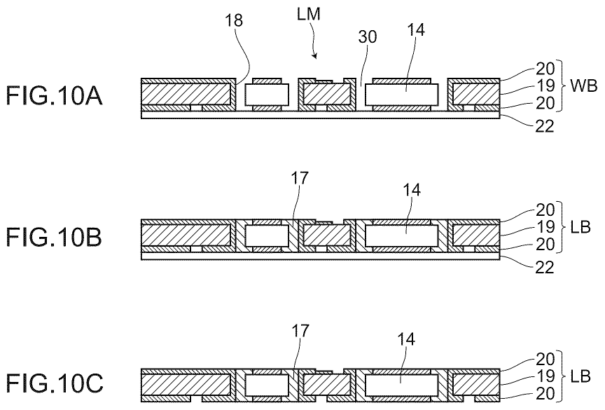

(2) In the above-mentioned respective embodiments (including the above-mentioned modifications and modifications described below), the wiring board stacked body is referred to the wiring board stacked body where the front surface and the back surface are insulated from each other. However, the present invention is not limited to such a configuration. The wiring board stacked body may be a wiring board stacked body where the front surface and the back surface communicate with each other. In this case, by forming a through hole in an opening formed in the wiring board material WB and plating to an inner surface of the through hole thus forming a plated through hole, it is possible to provide the wiring board stacked body where the front surface and the back surface become conductive with each other (the wiring board stacked body according to the modification 1, see FIG. 10A to FIG. 10C).

(3) In the above-mentioned respective embodiments, the metal layer 20 has the single-layer structure. However, in the present invention, the metal layer 20 is not limited to such a metal layer. The metal layer 20 may be a multi-layer wiring board having two or more layers.

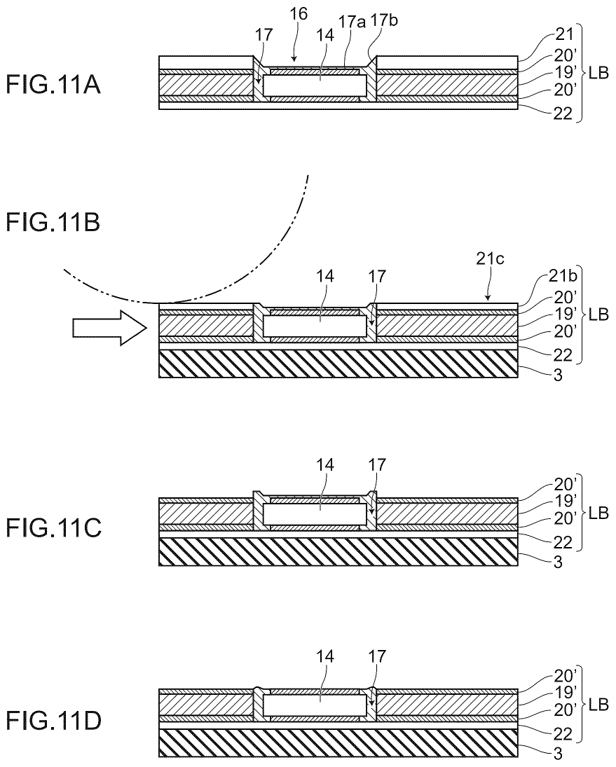

(4) In the above-mentioned respective embodiments, the example is exemplified where the stacked body LB is formed using the filling-use sheet 16′ containing the hardened material 17. However, the present invention is not limited to such a configuration. As illustrated in FIG. 11A, using a coating material that contains a hardened material 17, a stacked body LB where a hardened material 16 of a coating layer that has a recessed portion 17a above the embedded member 14 is integrated with the wiring board material WB′ is formed (see FIG. 11A), in performing a step of removing the hardened material 16 by grinding the hardened material 16 of the coating layer such that a thickness of the stacked body LB after grinding becomes a fixed value, a peripheral portion 17b of the hardened material 16 of the coating layer and a portion of a thickness of the resin film 21 are removed (see FIG. 11B), a remaining portion 21b of the resin film 21 is peeled off from the stacked body LB (see FIG. 11C), and the hardened material 16 of the coating layer on an upper surface of the embedded member 14 may be removed by polishing such as buff polishing, sand blasting or the like (see FIG. 11D).

(5) In the above-mentioned respective embodiments, the wiring board stacked body is manufactured using the wiring board material WB′ where the metal layer is formed on both surfaces of the ceramic body 13. However, the present invention is not limited to such a configuration, the wiring board stacked body may be manufactured using the wiring board material where a metal layer is formed on one surface of the ceramic body 13.

(6) In the above-mentioned respective embodiments, the metal film non-formed region is formed on both surfaces of an outer edge portion of the ceramic body. However, the present invention is not limited to such a configuration. A metal film non-formed region may be formed only on one surface of the outer edge portion of the ceramic body, and the metal film non-formed region may be filled with a hardened material, or the metal film non-formed region may be formed of only a portion of the outer edge portion of the ceramic body, and the metal film non-formed region may be filled with the hardened material.

(7) in the above-mentioned respective embodiments, the thickness of the metal film 15 of the embedded member 14 is set equal to the thickness of the metal layer 20 of the wiring board WB. However, the present invention is not limited to such a configuration. The thickness of the metal film 15 of the embedded member 14 may be different from the thickness of the metal layer 20 of the wiring abord WB. In a case where the thickness of the metal film 15 of the embedded member 14 is set thinner than the thickness of the metal layer 20 of the wiring abord WB, heat resistance at the time of transferring heat generated from an electronic element to a back surface side via the embedded member 14 can be made small and hence, it is possible to acquire an advantageous effect that the transfer of heat generated from the electronic element to the outside is further improved. Further, in a case where the thickness of the metal film 15 of the embedded member 14 is set thicker than the thickness of the metal layer 20 of the wiring board WB, it is possible to adjust a stress in the ceramic body 13 and a stress in the metal film 15.

1. A wiring board stacked body comprising:
a wiring board having an opening;
an embedded member embedded in an inside of the opening formed in the wiring board;
a hardened material containing a thermosetting resin, disposed between the embedded member and an inner peripheral surface of the opening, and adhered to the wiring board; and
a wiring layer formed on surfaces of the wiring board, the embedded member and the thermosetting resin, wherein
the embedded member includes a ceramic body, and metal films each formed on both surfaces of the ceramic body.

2. The wiring board stacked body according to claim 1, wherein a metal film non-formed region where the metal film is not formed is disposed on at least one surface of an outer edge portion of the embedded member, and
the hardened material is disposed also between the ceramic body and the wiring layer in the metal film non-formed region.

3. The wiring board stacked body according to claim 2, wherein the metal film non-formed region is formed on both surfaces of an outer edge portion of the embedded member, and
the hardened material is also disposed between the ceramic body and the wiring layer in the both metal film non-formed regions of the ceramic body.

4. The wiring board stacked body according to claim 1, wherein
as viewed in a plan view, the metal film non-formed region is formed on the entirety of the outer edge portion so as to surround the metal film.

5. The wiring board stacked body according to claim 1, wherein
the metal film is formed on a surface of the ceramic body by plating using direct plating.

6. The wiring board stacked body according to claim 1, wherein
a metal layer is disposed on a surface of the wiring board, and
a circuit wiring is constituted of the wiring layer, the metal layer and the metal film.

7. The wiring board stacked body according to claim 6, wherein the metal layer is a metal plated film that is formed on a surface of the wiring board by plating.

8. The wiring board stacked body according to claim 1, wherein
the opening has a rectangular shape, and the embedded member has a rectangular shape as viewed in a plan view.

9. A method of manufacturing a wiring board stacked body for manufacturing the wiring board stacked body described in claim 1, the method comprising the steps of:
obtaining a stacked body that includes: a wiring board or a wiring board material having an opening; an embedded member positioned in the opening; and a filling-use sheet or a hardened material of a coating layer containing a thermosetting resin that is integrated with the wiring board or the wiring board material, the thermosetting resin being filled between an inner surface of the opening formed in the wiring board or the wiring board material and the embedded member; and
removing the hardened material by grinding the filing-use sheet or the cure material of the coating layer such that a thickness of the stacked body after grinding becomes a fixed value.

10. The method of manufacturing a wiring board stacked body according to claim 9, further comprising the steps of:
preparing a stacked material that includes the wiring board or the wiring board material, the embedded member, and the filling-use sheet;
obtaining the stacked body by integrating the stacked material by heating and pressing, and
removing a hardened material of the filling-use sheet by grinding the hardened material of the filling-use sheet such that a thickness of the stacked body before grinding becomes a fixed value.

11. The method of manufacturing a wiring board stacked body according to claim 9, wherein
the stacked body is a stacked body where a resin film having an opening at a position that corresponds to the opening formed in the wiring board or the wiring board material is adhered to the wiring board or the wiring board material, and
the method further includes a step of setting a thickness of the stacked body after grinding to the thickness of the stacked body obtained by removing a portion of the resin film at a time of removing the hardened material of the filling-use sheet or the coating layer and, further, removing a remaining portion of the resin film from the stacked body; and
a step of removing the hardened material of a thermosetting resin that covers the embedded member of the stacked body.
